(19) United States
(12) Patent Application Publication
(10) Pub. No.: US 2008/0278917 A1
(43) Pub. Date: Nov. 13, 2008

(54) HEAT DISSIPATION MODULE AND METHOD FOR FABRICATING THE SAME

(75) Inventors: Shun-Tian Lin, Taipei (TW); Jyun-Wei Huang, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignees: Advanced Connectek Inc., Taipei (TW); Tysun Inc., Taipei County (TW)

(21) Appl. No.: 12/054,389

(22) Filed: Mar. 25, 2008

(30) Foreign Application Priority Data
May 7, 2007 (TW) 96116108

(51) Int. Cl. H05K 7/20; H05K 3/30

(52) U.S. Cl. 361/715; 361/704; 29/832

(57) ABSTRACT

A heat dissipation module including a substrate, a printed circuit board (PCB), and at least one light emitting diode (LED) chip is provided. A surface of the substrate has at least one positioning portion protruding upward. The PCB has at least one positioning hole corresponding to the positioning part. The PCB is disposed on the surface of the substrate, such that the positioning part is located in the positioning hole. The LED chip is disposed on the positioning part and electrically connected to the PCB.

### CROSS-REFERENCE TO RELATED APPLICATION

This application claims the priority benefit of Taiwan application serial no. 96116108, filed on May 7, 2007. The entirety the above-mentioned patent application is hereby incorporated by reference herein and made a part of specification.

### BACKGROUND OF THE INVENTION

1. Field of the Invention

The present invention generally relates to a heat dissipation module and a method for fabricating the same, in particular, to a heat dissipation module suitable for a high-power electronic device package and a method for fabricating the same.

2. Description of Related Art

With the advancement of technology, various electronic devices have been developed towards a trend of high power, being light, thin, short, and small. However, during the evolution process, “heat” is an inevitable problem. Therefore, it is a key technique for the current electronic technology development how to solve the heat dissipation problem.

According to early heat dissipation manners of the electronic devices, the generated heat is conducted to a packaging surface by means of a material of the device package, and then the heat is conducted onto a copper pipe or a heat sink fin, or a fan is used, so as to achieve a heat dissipation effect of forced convection. In a conventional printed circuit board (PCB), heat dissipation holes are increased, a metal film is plated, a heat sink compound is coated, or even a metal block is installed at the bottom of the PCB, so as to solve the problem of thermal resistance generated by the conventional board, thereby achieving the effect of improving the heat dissipation efficiency. The manner of additionally installing the metal block on the bottom of the substrate is most widely used due to simple and convenient construction, and the heat dissipation effect is good.

The structure with the metal block additionally installed on the PCB includes, from bottom to top, a metal base material for heat dissipation, a polymer PCB, and a wire structure printed on the substrate. The metal base material for heat dissipation can be copper, aluminum, a copper-based composite material, and an aluminum-base composite material, or various metal materials having high thermal conductivity coefficient. The PCB can be a single-layer or multilayer substrate according to requirements. The electronic device generating the heat source is installed on the PCB, thus the thermal energy generated during the operation of the electronic device can be successively conducted to the environment through the additionally installed high thermal-conductivity metal base material, thereby achieving the heat dissipation effect.

However, when being conducted to the metal base material, the heat must pass through the PCB. The PCB is made of a polymer, and can be considered as a huge thermal resistor, such that the thermal energy is massively accumulated and cannot be conducted to the metal block, thus seriously affecting the overall heat dissipation effect. Using a ceramic substrate having high thermal conductivity coefficient is a method of solving the problem of high-power electronic device packaging, but the price and the processing difficulties limit the scope of application.

Therefore, it is necessary to develop a heat dissipation module having high thermal conductivity and electrical insulation and capable of being soldered or wire bonded at an extremely high heat-generation power, so as to solve the current heat dissipation problem encountered in the packaging of the high heat-generation power electronic device.

### SUMMARY OF THE INVENTION

Accordingly, the present invention is directed to a heat dissipation module and a method for fabricating the same, suitable for solving the heat dissipation problem encountered in the packaging of the conventional high-efficiency electronic devices.

The present invention provides a heat dissipation module, which includes a substrate, a printed circuit board (PCB), and at least one light emitting diode (LED) chip. A surface of the substrate has at least one positioning portion protruding upward. The PCB has at least one positioning hole corresponding to the positioning portion, and the PCB is disposed on the surface of the substrate, such that the positioning portion is located in the positioning hole. The LED chip is disposed on the positioning portion, and is electrically connected to the PCB.

In an embodiment of the present invention, the substrate is made of a metal material. Further, the metal material is selected from a group consisting of copper, a copper alloy, aluminum, an aluminum alloy, and a composite material of copper and aluminum.

In an embodiment of the present invention, the substrate further has a positioning frame, disposed on the surface, so as to limit a position of the PCB on the substrate.

In an embodiment of the present invention, a height of the positioning portion is not greater than a thickness of the PCB.

In an embodiment of the present invention, the heat dissipation module further includes a plurality of cooling fins, disposed on a bottom of the substrate.

In an embodiment of the present invention, the heat dissipation module further includes a plurality of bonding wires, connected between the LED chip and the PCB.

In an embodiment of the present invention, the heat dissipation module further includes a molding compound, disposed on the PCB to cover the LED chip.

The present invention provides a method for fabricating a heat dissipation module, which includes the following steps. Firstly, a substrate, a PCB, and at least one LED chip are provided, in which a surface of the substrate has at least one positioning portion protruding upward, and the PCB has at least one positioning hole corresponding to the positioning portion. Next, the PCB is fixed on the surface of the substrate, such that the positioning portion is accommodated in the positioning hole. Then, the LED chip is fixed on the positioning portion. Finally, the LED chip and the PCB are electrically connected.

In an embodiment of the present invention, the substrate is made of a metal material. Further, the metal material is selected from a group consisting of copper, a copper alloy, aluminum, an aluminum alloy, and a composite material of copper and aluminum.

In an embodiment of the present invention, the substrate further has a positioning frame, disposed on the surface to limit a position of the PCB on the substrate.

In an embodiment of the present invention, a height of the positioning portion is not greater than a thickness of the PCB.

In an embodiment of the present invention, the substrate further includes a plurality of cooling fins, disposed on a bottom of the substrate.

In an embodiment of the present invention, in the step of electrically connecting the LED chip and the PCB, a plurality of bonding wires is formed between the LED chip and the PCB by a wire bonding technique, such that the LED chip is electrically connected to the PCB through the bonding wires.

In an embodiment of the present invention, after the step of electrically connecting the LED chip and the PCB, the method further includes forming a molding compound on the PCB to cover the LED chip.

In the heat dissipation module of the present invention, the LED chips are directly fixed on the substrate having the high thermal conductivity properties. Therefore, the thermal energy generated during the operation of the chip can be directly dissipated from the bottom of the substrate, so as to effectively solve the current heat dissipation problem encountered in the packaging of the electronic device.

In order to make the features and advantages of the present invention clearer and more understandable, the following embodiments are illustrated in detail with reference to the appended drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a heat dissipation module according to an embodiment of the present invention.

FIGS. 2A and 2B are schematic cross-sectional views of the heat dissipation module in FIG. 1 with cooling fins additionally installed on the bottom of the substrate.

FIG. 3 is a schematic cross-sectional view of a heat dissipation module according to another embodiment of the present invention.

FIGS. 4A to 4E are flow charts of the fabrication of a heat dissipation module according to an embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

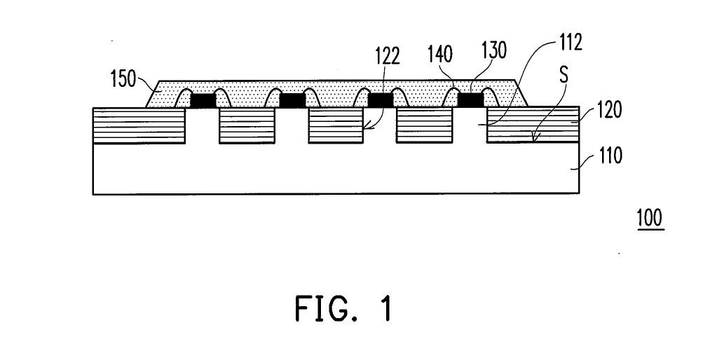

FIG. 1 is a schematic cross-sectional view of a heat dissipation module according to an embodiment of the present invention. Referring to FIG. 1, a heat dissipation module 100 of the present invention mainly includes a substrate 110, a PCB 120, and at least one LED chip 130. In this embodiment, for example, a plurality of LED chips 130 is disposed on the substrate 110, while merely one LED chip 130 can also be disposed on the substrate 110. In the present invention, the number of the LED chips 130 is not limited. Hereinafter, each component included in the heat dissipation module 100 and the connection relation therebetween are described with reference to the figures.

A surface S of the substrate 110 has a plurality of positioning portions 112 protruding upward. The LED chips 130 are directly disposed on the positioning portions 112 of the substrate 110, thus the substrate 110 is necessarily to adopt a material having high thermal conductivity properties, for dissipating the thermal energy generated by the chip during the operation. In an embodiment of the present invention, the substrate 110 can be fabricated by a metal material having high thermal conductivity properties, for example, copper, a copper alloy, aluminum, an aluminum alloy, and a composite material of copper and aluminum, or any other suitable thermal conductive material. The PCB 120 is fixed on the surface S of the substrate 110, and has a plurality of positioning holes 122 corresponding to the positioning portions 112, such that the positioning portions 112 can be accommodated in the positioning holes 122. By means of the combination of the positioning portion 112 and the positioning hole 122, the PCB 120 can also be fixed on the substrate 110, so as not to sway with respect to the substrate 110. In addition, in this embodiment, the height of the positioning portion 112 is equal to the thickness of the PCB 120, i.e., the positioning portion 112 and the PCB 120 are coplanar.

The plurality of LED chips 130 is respectively disposed on the corresponding positioning portions 112, and is electrically connected to the PCB 120. In this embodiment, the heat dissipation module 100 further includes a plurality of bonding wires 140, connected between the LED chips 130 and the PCB 120, such that the LED chips 130 are electrically connected to the PCB 120 through the bonding wires 140. In addition, as shown in FIG. 1, a molding compound 150 can be selectively disposed on the PCB 120, and the molding compound 150 covers the LED chips 130 and the bonding wires 140, so as to protect them from being damaged and being affected by moisture.

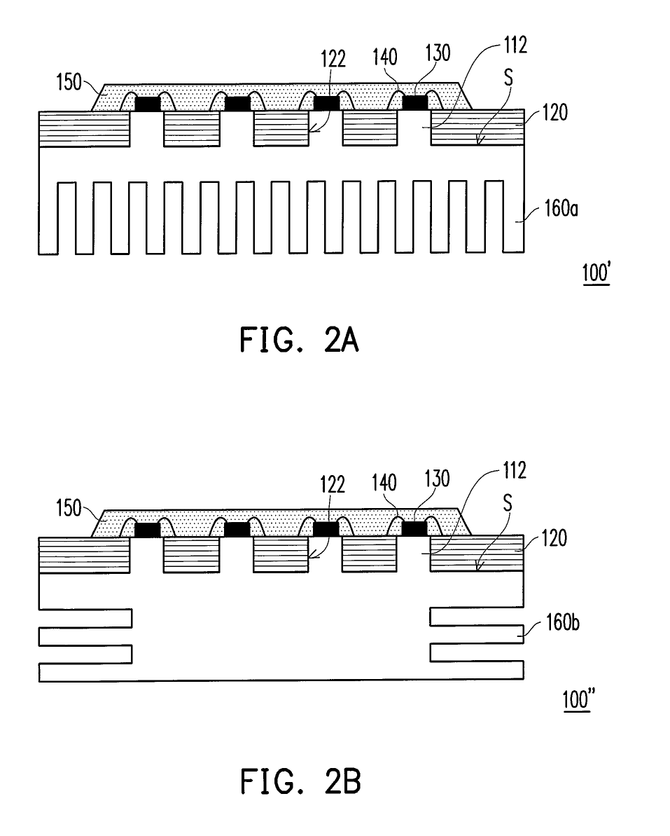

In order to further improve the heat dissipation efficiency of the substrate 110, as shown in FIGS. 2A and 2B, heat dissipation modules 100′ and 100″ can further include a plurality of cooling fins 160a or cooling fins 160b, so as to increase the heat dissipation area for heat convection.

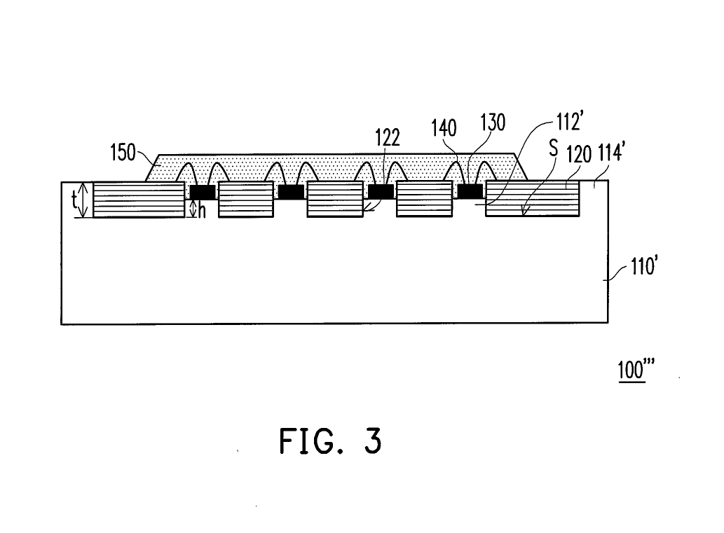

FIG. 3 is a schematic cross-sectional view of a heat dissipation module according to another embodiment of the present invention. Referring to FIG. 3, the structure of a heat dissipation module 100′″ is the same as that of the heat dissipation module 100 in FIG. 1, except that in the heat dissipation module 100′″, the height h of the positioning portion 112′ of the substrate 110′ is less than the thickness t of the PCB 120. In this manner, a recess is formed between the PCB 120 and each positioning portion 112′, for accommodating the LED chip 130. In addition, a positioning frame 114′ can be disposed on a surface S of the substrate 110′, for limiting a position of the PCB 120 on the substrate 110′.

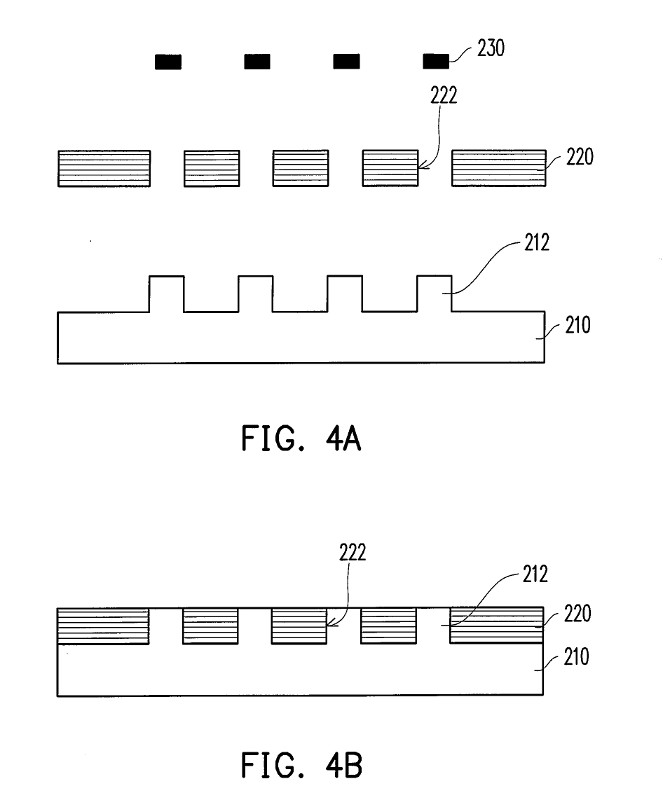

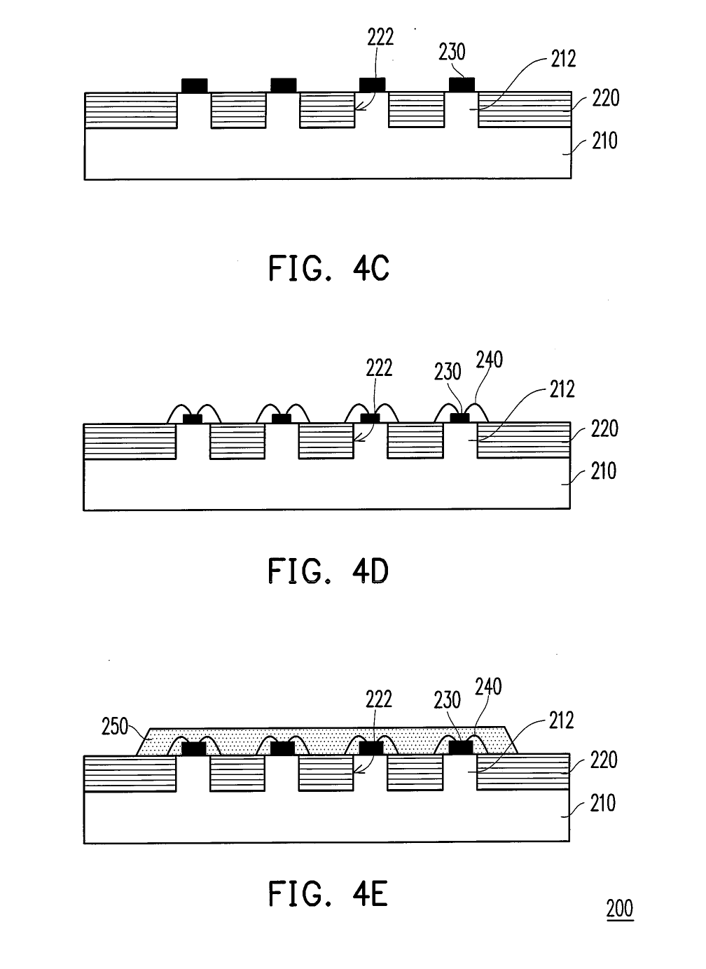

FIGS. 4A to 4E are schematic cross-sectional views of the fabrication process of a heat dissipation module according to an embodiment of the present invention. Firstly, referring to FIG. 4A, a substrate 210, a PCB 220, and a plurality of LED chips 230 are provided. In this embodiment, for example, a plurality of LED chips 230 is disposed on the substrate 210, while merely one LED chip 230 can also be disposed on the substrate 210. In the present invention, the number of the LED chips 230 is not limited. As shown in FIG. 4A, a surface S of the substrate 210 has a plurality of positioning portions 212 protruding upward, and the PCB 220 has a plurality of positioning holes 222 corresponding to the positioning portions 212. In an embodiment of the present invention, the substrate 110 can be fabricated by a metal material having high thermal conductivity properties, such as copper, a copper alloy, aluminum, an aluminum alloy, and a composite material of copper and aluminum, or any other suitable thermal conductive material.

Next, referring to FIG. 4B, the PCB 220 is fixed on the surface S of the substrate 210, such that the positioning portions 212 are accommodated in the positioning holes 222, thus a composite substrate having the thermal conduction function and circuit control function is formed. Then, referring to FIG. 4C, the LED chips 230 are fixed on the positioning portions 212. In an embodiment of the present invention, the LED chips 230 can be fixed on the positioning portions 212 by using an adhesive (not shown). Finally, referring to FIG. 4D, the LED chips 230 and the PCB 220 are electrically connected, thereby completing the fabrication process of the heat dissipation module 200. In this embodiment, a plurality of bonding wires 240 is formed between the LED chips 230 and the PCB 220 by the wire bonding technology, such that the LED chips 230 are electrically connected to the PCB 220 through the bonding wires 240.

After completing the fabrication process of the heat dissipation module 200, as shown in FIG. 4E, a molding compound 250 can be selectively formed on the PCB 220. The molding compound 250 covers the LED chips 230 and the bonding wires 240, so as to protect them from being damaged or being affected by moisture.

However, the positioning frame 114′ in FIG. 3 can also be disposed on the substrate 210 to further limit the position of the PCB 220 on the substrate 210. Additionally, the height of the positioning portion 212 can also be less than the thickness of the PCB 220. In the present invention, the height of the positioning portion 212 is not limited. Further, in order to further improve the heat dissipation effect of the substrate 210, a plurality of cooling fins can also be designed at the bottom of the substrate 210, as shown in FIG. 2A or 2B, so as to increase the heat dissipation area.

In view of the above, in the heat dissipation module of the present invention, the composite structure having high thermal conductivity properties and the circuit control function is formed mainly by combining the positioning portions of the substrate and the positioning holes of the PCB. Then, the LED chips are disposed on the positioning portion of the substrate, and are electrically connected to the PCB, thus the heat dissipation module is formed.

In the heat dissipation module, the LED chips are directly fixed on the substrate having high thermal conductivity properties. Therefore, the thermal energy generated during the operation of the chip can be directly dissipated from the bottom of the substrate, so as to effectively solve the current heat dissipation problem encountered in the packaging of the electronic device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A heat dissipation module, comprising:
a substrate, wherein a surface of the substrate comprises at least one positioning portion protruding upward;
a printed circuit board (PCB), comprising at least one positioning hole corresponding to the positioning portion, wherein the PCB is disposed on the surface of the substrate, such that the positioning portion is located in the positioning hole; and
at least one LED chip, disposed on the positioning portion, and electrically connected to the PCB.

2. The heat dissipation module according to claim 1, wherein the substrate is made of a metal material.

3. The heat dissipation module according to claim 2, wherein the metal material is selected from a group consisting of copper, a copper alloy, aluminum, an aluminum alloy, and a composite material of copper and aluminum.

4. The heat dissipation module according to claim 1, wherein the substrate further comprises a positioning frame disposed on the surface, so as to limit a position of the PCB on the substrate.

5. The heat dissipation module according to claim 1, wherein a height of the positioning portion is not greater than a thickness of the PCB.

6. The heat dissipation module according to claim 1, further comprising a plurality of cooling fins disposed on a bottom of the substrate.

7. The heat dissipation module according to claim 1, further comprising a plurality of bonding wires connected between the LED chip and the PCB.

8. The heat dissipation module according to claim 1, further comprising a molding compound disposed on the PCB, so as to cover the LED chip.

9. A method for fabricating a heat dissipation module, comprising:
providing a substrate, a PCB, and at least one LED chip, wherein a surface of the substrate comprises at least one positioning portion protruding upward, and the PCB comprises at least one positioning hole corresponding to the positioning portion;
fixing the PCB on the surface of the substrate, such that the positioning portion is accommodated in the positioning hole;
fixing the LED chip on the positioning portion; and
electrically connecting the LED chip and the PCB.

10. The method for fabricating a heat dissipation module according to claim 9, wherein the substrate is made of a metal material.

11. The method for fabricating a heat dissipation module according to claim 10, wherein the metal material is selected from a group consisting of copper, a copper alloy, aluminum, an aluminum alloy, and a composite material of copper and aluminum.

12. The method for fabricating a heat dissipation module according to claim 9, wherein the substrate further comprises a positioning frame disposed on the surface, so as to limit a position of the PCB on the substrate.

13. The method for fabricating a heat dissipation module according to claim 9, wherein a height of the positioning portion is not greater than a thickness of the PCB.

14. The method for fabricating a heat dissipation module according to claim 9, wherein the substrate further comprising a plurality of cooling fins disposed on a bottom of the substrate.

15. The method for fabricating a heat dissipation module according to claim 9, wherein in the step of electrically connecting the LED chip and the PCB, a plurality of bonding wires is formed between the LED chip and the PCB by a wire bonding technique, such that the LED chip is electrically connected to the PCB through the bonding wires.

16. The method for fabricating a heat dissipation module according to claim 9, wherein after the step of electrically connecting the LED chip and the PCB, the method further comprises a step of forming a molding compound on the PCB, so as to cover the LED chip.
